(19) United States
(12) Patent Application Publication
(10) Pub. No.: US 2017/0181309 A1
(43) Pub. Date: Jun. 22, 2017

(54) ELECTRONIC ASSEMBLY

(71) Applicant: GIGA-BYTE TECHNOLOGY CO.,LTD., New Taipei City (TW)

(72) Inventor: Chieh-Shih Yi, New Taipei City (TW)

(21) Appl. No.: 15/051,615

(22) Filed: Feb. 23, 2016

(30) Foreign Application Priority Data
Dec. 17, 2015 (TW) 104142472

(51) Int. Cl. H05K 7/14

(52) U.S. Cl. CPC H05K 7/1417; H05K 7/1422

(57) ABSTRACT

An electronic assembly includes a supporting structure, a circuit board and at least one elastic component. The circuit board has at least one assembling hole and a first electrical connector, the circuit board is assembled to the supporting structure through the assembling hole, and the first electrical connector is adapted to connect to a second electrical connector. The elastic component is disposed at the assembling hole and includes at least one first compressible portion and a second compressible portion connected to each other. The first compressible portion is located outside the assembling hole and adapted to be compressed between the supporting structure and the circuit board along a first direction. The second compressible portion is located inside the assembling hole and adapted to be compressed between the supporting structure and the circuit board along a second direction and a third direction. The first, second and third directions are mutually perpendicular.

### CROSS-REFERENCE TO RELATED APPLICATION

This non-provisional application claims priority under 35 U.S.C. §119(a) on Patent Application No. 104142472, filed in Taiwan on Dec. 17, 2015, the entirety of which is incorporated herein by reference.

### BACKGROUND OF THE INVENTION

Field of the Invention

The invention relates to an electronic assembly, and particularly, to an electronic assembly including a circuit board.

Description of Related Art

A server is a core for servicing each computer or portable electronic device in a network system. Generally speaking, the server is made up of a framework and a plurality of machine cases disposed in the framework. A basic configuration of each of the machine cases is similar to that of a personal computer and includes a central processing unit (CPU), a memory and an input output (I/O) device and such parts.

Each of the machine cases may be pulled out from the framework for performing maintenance or changing out parts and may be pushed in and connected to the framework to operate normally, wherein each of the machine cases is connected to a connector on the framework through an electrical connector of the circuit board which is on the machine case. However, an error margin in the manufacturing and assembly of the framework and the machine case may make the electrical connector and the connector not align properly, resulting in a non smooth insertion which causes inconvenience to the operation of the server. In addition, when the machine case is pushed in and connected to the framework, a collision between the machine case and the framework may cause damage to the circuit board and the components thereon due to excessive vibration.

### SUMMARY OF THE INVENTION

Accordingly, it is an object of the invention to provide an electronic assembly, wherein a first electrical connector on a circuit board of the electronic assembly may be inserted to a corresponding second electrical connector smoothly, and the electronic assembly has a good vibration damping effect.

To achieve the above-mentioned object, according to the invention, an electronic assembly of the invention includes a supporting structure, a circuit board and at least one elastic component. The circuit board has at least one assembling hole and a first electrical connector, the circuit board is assembled to the supporting structure through the assembling hole, and the first electrical connector is adapted to connect to a second electrical connector. The elastic component is disposed at the assembling hole, the elastic component includes at least one first compressible portion and a second compressible portion connected to each other. The first compressible portion is located outside the assembling hole and adapted to be compressed between the supporting structure and the circuit board along a first direction. The second compressible portion is located inside the assembling hole and adapted to be compressed between the supporting structure and the circuit board along a second direction and a third direction. The first direction, the second direction and the third direction are mutually perpendicular.

In an embodiment of the invention, the supporting structure includes a supporting plate and at least one fixing component, the supporting plate supports the circuit board, the fixing component includes a through portion and a restricting portion connected to each other, the elastic component has a through hole, the through portion penetrates the through hole and connects to the supporting plate, the restricting portion restricts the elastic component and the circuit board on the supporting plate.

In an embodiment of the invention, the first compressible portion is located between the restricting portion and the circuit board or located between the supporting plate and the circuit board, and is adapted to be compressed by the restricting portion and the circuit board along the first direction or to be compressed by the supporting plate and the circuit board along the first direction.

In an embodiment of the invention, the second compressible portion is located between the through portion and an inner wall of the assembling hole, and is adapted to be compressed by the through portion and the circuit board along the second direction and the third direction.

In an embodiment of the invention, an outer diameter of the restricting portion along the second direction and the third direction is greater than an outer diameter of the through portion along the second direction and the third direction.

In an embodiment of the invention, a hole diameter of the assembling hole along the second direction and the third direction is greater than an outer diameter of the restricting portion along the second direction and the third direction.

In an embodiment of the invention, a thickness of the elastic component along the first direction is greater than or equal to a thickness of the through portion along the first direction.

In an embodiment of the invention, the fixing component includes a threaded portion, the threaded portion is connected to the restricting portion and screwed to the through portion.

In an embodiment of the invention, the through portion includes at least one elastic arm, the restricting portion is connected to the elastic arm and is adapted to pass through the through hole by an elastic deformation of the elastic arm.

In an embodiment of the invention, the second compressible portion contacts an inner wall of the assembling hole and the through portion simultaneously.

In an embodiment of the invention, the at least one first compressible portion comprises two first compressible portions, the second compressible portion is connected between the two first compressible portions, the two first compressible portions are located at two opposite sides of the circuit board respectively.

In an embodiment of the invention, a material of the elastic component is an insulation material.

In an embodiment of the invention, the circuit board has a slot, the slot is connected between a side edge of the circuit board and the assembling hole.

In an embodiment of the invention, the second electrical connector is disposed on a frame, the first electrical connector is adapted to connect to the second electrical connector by moving the supporting structure along the frame.

In an embodiment of the invention, the first electrical connector is a terminal assembly independently disposed on the circuit board or a card edge connector.

Based on the above, in an electronic assembly of the invention, an elastic component is disposed at an assembling hole of a circuit board, and the elastic component has a first compressible portion located outside the assembling hole and a second compressible portion located inside the assembling hole. When a first electrical connector on the circuit board is inserted to a corresponding second electrical connector, the elastic component may absorb an error margin in the manufacturing and assembly of the electronic assembly in a first direction by an elastic compression of the first compressible portion along the first direction, and absorb the error margin in the manufacturing and assembly of the electronic assembly in a second direction and a third direction by the elastic compression of the second compressible portion along the second direction and the third direction, such that the first electrical connector may be inserted to the corresponding second electrical connector smoothly. The first direction, the second direction and the third direction are three axis directions mutually perpendicular to each other in space, namely, the elastic component may absorb the error margins in the manufacturing and assembly of the electronic assembly in all directions by the elastic compression of the first compressible portion and the second compressible portion.

Several exemplary embodiments accompanied with figures are described in detail below to further describe the disclosure in details.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a partial perspective diagram of an electronic assembly according to an embodiment of the invention;

FIG. 2 illustrates a first electrical connector of FIG. 1 separated from a second electrical connector;

FIG. 3 is a perspective diagram of a circuit board of FIG. 1;

FIG. 4 is a perspective diagram of a circuit board and an elastic component of FIG. 1;

FIG. 5 is a partial side view diagram of the electrical assembly of FIG. 1;

FIG. 6A and FIG. 6B illustrate a first compressible portion of FIG. 5 being compressed;

FIG. 6C and FIG. 6D illustrate a second compressible portion of FIG. 5 being compressed;

FIG. 7 is a partial side view diagram of an electronic assembly according to another embodiment of the invention; and

FIG. 8 is a partial plan view diagram of a circuit board and an elastic component according to another embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

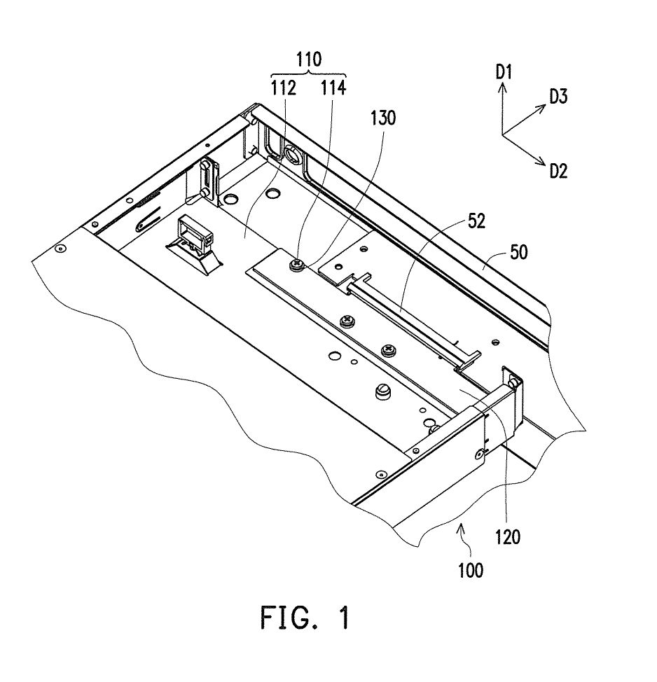

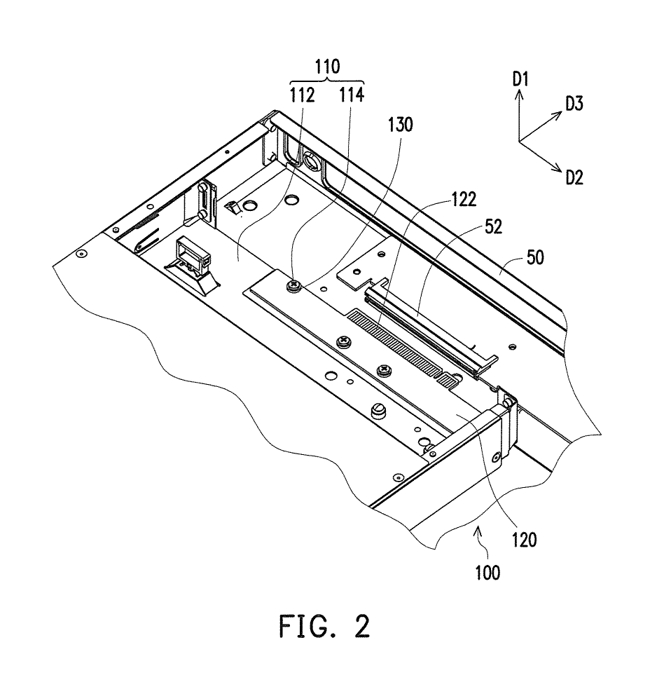

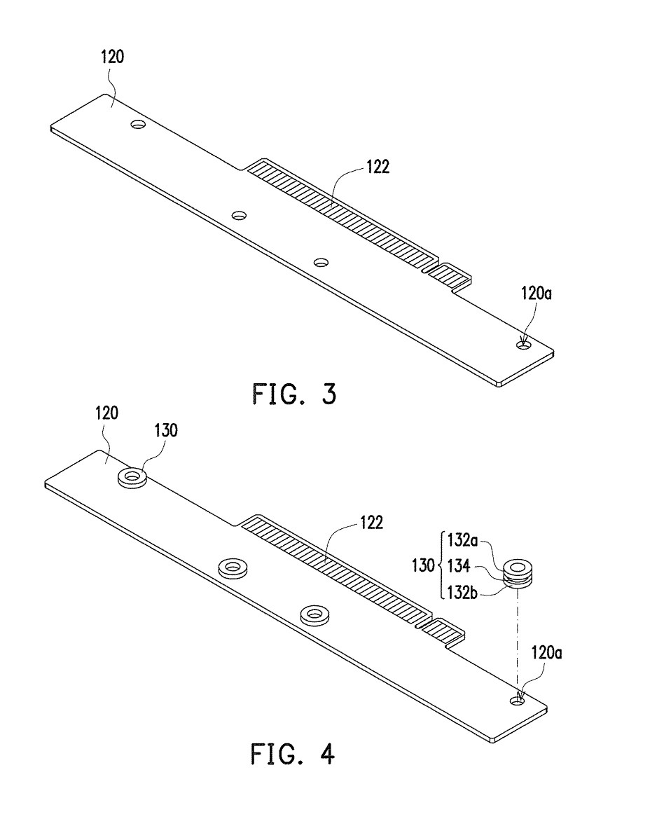

FIG. 1 is a partial perspective diagram of an electronic assembly according to an embodiment of the invention. FIG. 2 illustrates a first electrical connector of FIG. 1 separated from a second electrical connector. FIG. 3 is a perspective diagram of a circuit board of FIG. 1. Referring to FIG. 1 through FIG. 3, an electronic assembly 100 includes a supporting structure 110 and a circuit board 120. The circuit board 120 has a first electrical connector 122 and at least one assembling hole 120a (a plurality are shown), and assembled to the supporting structure 110 through the assembling hole 120a.

In the present embodiment, the electronic assembly 100, for example, is applicable to a server, the supporting structure 110 is a base plate of a machine case of the server, and a frame 50 is a framework of the server. The first electrical connector 122 of the circuit board 120 may be connected to second electrical connector 52 on the frame 50 by moving the supporting structure 110 along the frame 50 as shown in FIG. 1, and may be separated from the second electrical connector 52 by moving the supporting structure 110 along the frame 50 as shown in FIG. 2. The first electrical connector 122, for example, is a card edge connector (commonly known as a gold finger connector) and also may be a terminal assembly independently disposed on the circuit board 120 or other type of electrical connection terminal. A type of the second electrical connector 52 corresponds with the type of the first electrical connector 122. In other embodiments, the electronic assembly 100 may be applicable to other types of devices and is not limited hereto.

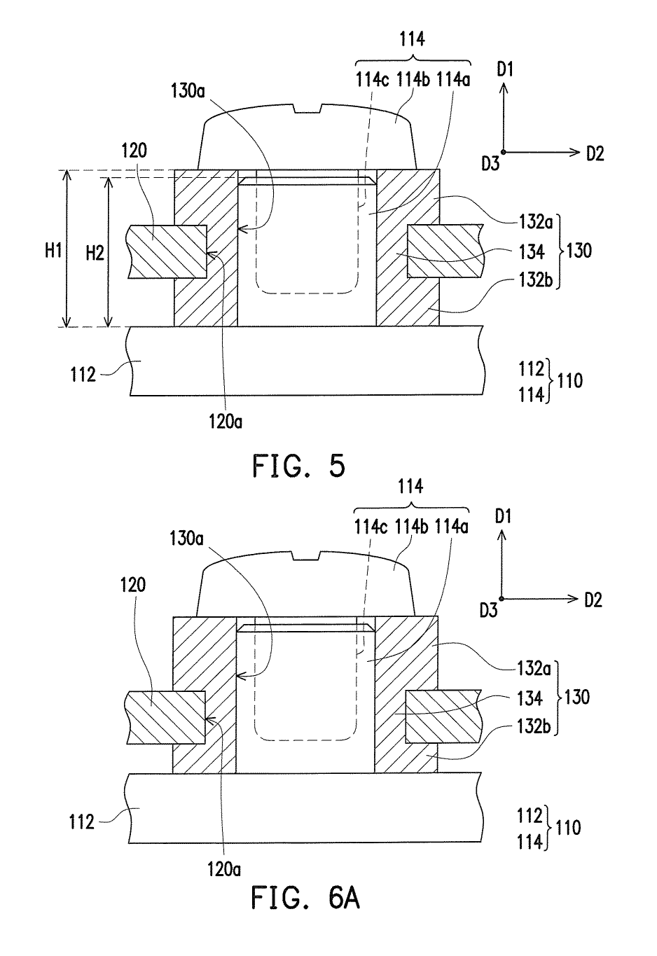

FIG. 4 is a perspective diagram of a circuit board and an elastic component of FIG. 1. FIG. 5 is a partial side view diagram of the electrical assembly of FIG. 1. In order to make the figures more clear, one elastic components 130 separated from the circuit board 120 is illustrated in FIG. 4 and a cross section of the circuit board 120 and the elastic components 130 is illustrated in FIG. 5. Referring to FIG. 3 through FIG. 5, the electronic assembly 100 (labelled in FIG. 1) further includes at least one elastic component 130 (a plurality are illustrated), and the elastic components 130 are disposed at the assembling holes 120a. Each of the elastic components 130 includes at least one first compressible portion (two first compressible portions 132a, 132b are illustrated) and a second compressible portion 134 connected to each other. The second compressible portion 134 is connected between the first compressible portions 132a, 132b. The first compressible portions 132a, 132b are located on two opposite sides of the circuit board 120 respectively and are located outside the assembling hole 120a, and are adapted to be compressed between the supporting structure 110 and the circuit board 120 along a first direction D1. The second compressible portion 134 is located inside the assembling hole 120a and adapted to be compressed between the supporting structure 110 and the circuit board 120 along a second direction D2 and a third direction D3.

When the first electrical connector 122 (illustrated in FIG. 2 through FIG. 4) on the circuit board 120 is inserted to the corresponding second electrical connector 52 (illustrated in FIG. 1 and FIG. 2), each of the elastic components 130 may absorb an error margin in the manufacturing and assembly of the electronic assembly 100 in the first direction D1 by the elastic compression of the first compressible portion 132a, 132b along the first direction D1, and absorb the error margin in the manufacturing and assembly of the electronic assembly 100 in the second direction D2 and the third direction D3 by the elastic compression of the second compressible portion 134 along the second direction D2 and the third direction D3, such that the first electrical connector 122 may be inserted to the corresponding second electrical connector 52 smoothly. The first direction D1, the second direction D2 and the third direction D3 are three axial directions mutually perpendicular to each other in space, namely, each of the elastic components 130 may absorb the error margins in the manufacturing and assembly of the electronic assembly 100 in all directions by the elastic compression of the first compressible portion 132a, 132b and the second compressible portion 134. In addition during the process of inserting the first electrical connector 122 to the corresponding second electrical connector 52, each of the elastic components 130 may cushion the impact generated by the insertion, such that the electronic assembly 100 may have a good vibration damping effect to prevent the circuit board 120 and the components thereon from being damaged during the insertion process due to excessive vibration.

Referring to FIG. 5, more specifically, the supporting structure 110 of the present embodiment includes a supporting plate 112 and at least one fixing component 114 (a plurality are illustrated in FIG. 1 and FIG. 2). The supporting plate 112 supports the circuit board 120. Each of the fixing components 114 includes a through portion 114a and a restricting portion 114b connected to each other. Each of the elastic components 130 have a through hole 130a. The through portion 114a passes through the through hole 130a and is connected to the supporting plate 112. A location of the elastic components 130 and the circuit board 120 are restricted on the supporting plate 112 by the restricting portion 114b.

The first compressible portion 132a is located between the restricting portion 114b and the circuit board 120 and is adapted to be compressed by the restricting portion 114b and the circuit board 120 along the first direction D1. The first compressible portion 132b is located between the supporting plate 112 and the circuit board 120 and is adapted to be compressed by the supporting plate 112 and the circuit board 120 along the first direction D1. The second compressible portion 134 is located between the through portion 114a and an inner wall of the assembling hole 120a, and is adapted to be compressed by the through portion 114a and the circuit board 120 along the second direction D2 and the third direction D3.

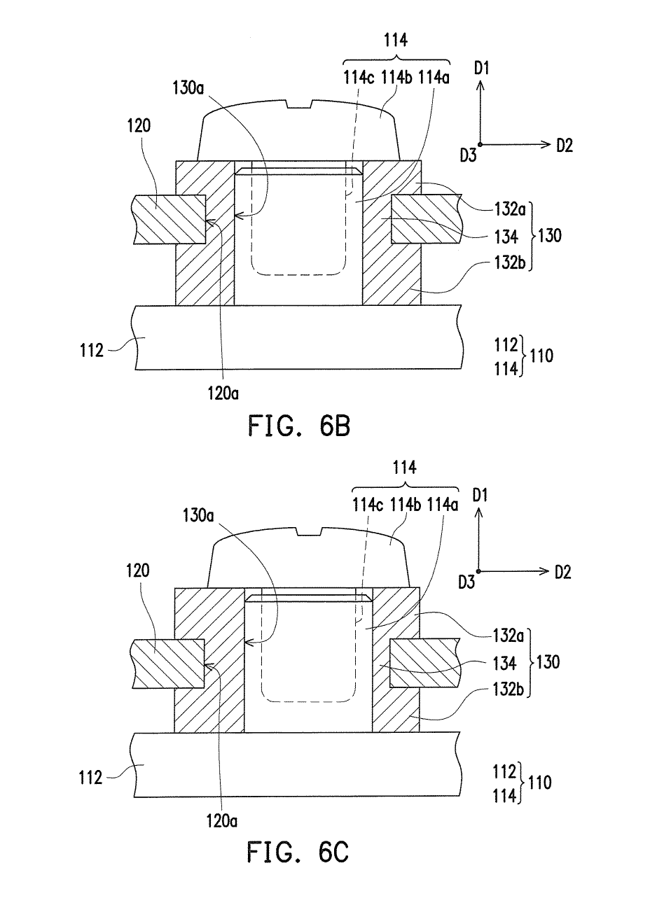

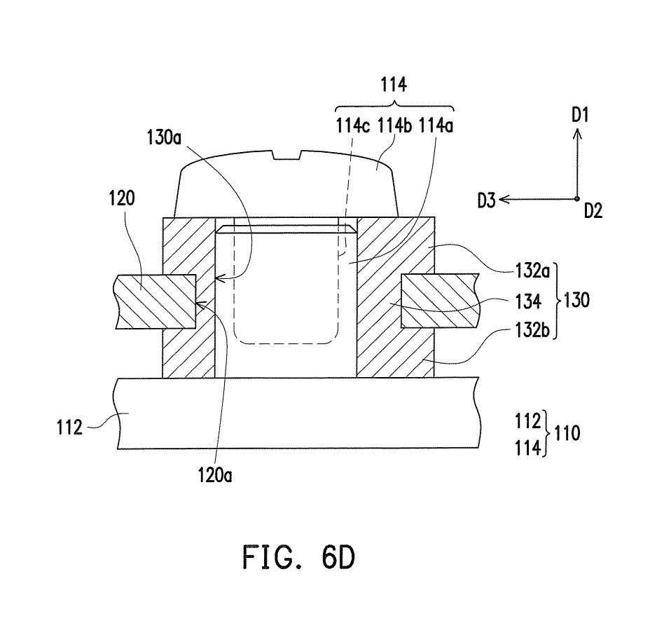

FIG. 6A and FIG. 6B illustrate a first compressible portion of FIG. 5 being compressed. FIG. 6C and FIG. 6D illustrate a second compressible portion of FIG. 5 being compressed. For example, if a location of the first electrical connector 122 shown in FIG. 2 in the first direction D1 is slightly higher than a location of the second electrical connector 52 in the first direction D1 due to the error margin in the manufacturing and assembly, then when the first electrical connector 122 is connected to the second electrical connector 52, the first compressible portion 132b of the elastic components 130 may be compressed by the supporting plate 112 and the circuit board 120 along the first direction D1 as shown in FIG. 6A, such that the circuit board 120 may generate a downward position shift to allow the first electrical connector 122 and the second electrical connector 52 to connect smoothly and to prevent a non smooth insertion of the first electrical connector 122 and the second electrical connector 52 due to an alignment deviation in the first direction D1. If the location of the first electrical connector 122 shown in FIG. 2 in the first direction D1 is slightly lower than the location of the second electrical connector 52 in the first direction D1 due to the error margin in the manufacturing and assembly, then when the first electrical connector 122 is connected to the second electrical connector 52, the first compressible portion 132a of the elastic components 130 may be compressed by the restricting portion 114b and the circuit board 120 along the first direction D1 as shown in FIG. 6B, such that the circuit board 120 may generate an upward position shift to allow the first electrical connector 122 and the second electrical connector 52 to connect smoothly and to prevent a non smooth insertion of the first electrical connector 122 and the second electrical connector 52 due to an alignment deviation in the first direction D1.

Accordingly, if there is an alignment deviation between the first electrical connector 122 shown in FIG. 2 and the second electrical connector 52 in the second direction D2 due to the error margin in the manufacturing and assembly, then when the first electrical connector 122 is connected to the second electrical connector 52, the second compressible portion 134 of the elastic components 130 may be compressed by the through portion 114a and the circuit board 120 along the second direction D2 as shown in FIG. 6C, such that the circuit board 120 may generate a horizontal position shift to allow the first electrical connector 122 and the second electrical connector 52 to connect smoothly and to prevent a non smooth insertion of the first electrical connector 122 and the second electrical connector 52 due to an alignment deviation in the second direction D2. In addition, if there is an alignment deviation between the first electrical connector 122 shown in FIG. 2 and the second electrical connector 52 in the third direction D3 due to the error margin in the manufacturing and assembly, then when the first electrical connector 122 is connected to the second electrical connector 52, the second compressible portion 134 of the elastic components 130 may be compressed by the through portion 114a and the circuit board 120 along the third direction D3 as shown in FIG. 6D, such that the circuit board 120 may generate a horizontal position shift to allow the first electrical connector 122 and the second electrical connector 52 to connect accurately and to prevent an incomplete connection of the first electrical connector 122 and the second electrical connector 52 due to an alignment deviation in the third direction D3, to ensure a stability of the signal transmission.

Referring to FIG. 5, in the present embodiment, a thickness H1 of the elastic components 130 along the first direction D1, for example, is greater than or equal to a thickness H2 of the through portion 114a along the first direction D1, such that the first compressible portion 132a is able to be compressed between the restricting portion 114b and the circuit board 120, and such that the first compressible portion 132b is able to be compressed between the supporting plate 112 and the circuit board 120. In other embodiments, the elastic components 130 and the through portion 114a may be other suitable thicknesses and it should not be construed as a limitation to the invention. In addition, in the present embodiment, the second compressible portion 134 contacts the inner wall of the assembling hole 120a and the through portion 114a simultaneously, such that the second compressible portion 134 is able to be compressed between the through portion 114a and the circuit board 120.

A material of the elastic components 130, for example, is an insulation material to prevent unintended electrical connection between the circuit board 120 and the supporting structure 110. For example, the material of the elastic components 130 may be rubber, foam or other suitable type of insulating elastic material and it should not be construed as a limitation to the invention.

In the present embodiment, the fixing component 114, for example, is made up of a stud and a screw. More specifically, the through portion 114a is the stud and the restricting portion 114b is a head of the screw. The fixing component 114 further includes a threaded portion 114c, wherein the threaded portion 114c is connected to the restricting portion 114b and screwed to the through portion 114a. However, the configuration of the fixing component 114 should not be construed as a limitation to the invention and will be described below with examples using the figures.

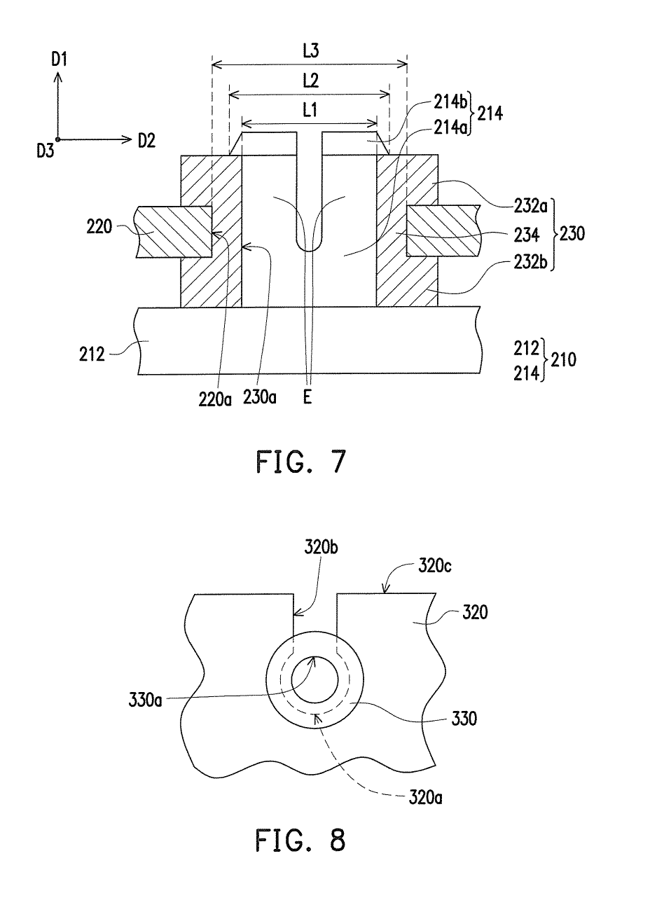

FIG. 7 is a partial side view diagram of an electronic assembly according to another embodiment of the invention. In the embodiment shown in FIG. 7, a configuration and operating mechanism of a supporting structure 210, a supporting plate 212, a fixing component 214, a circuit board 220, an assembling hole 220a, an elastic components 230, a through hole 230a, a first compressible portion 232a, a first compressible portion 232b, a second compressible portion 234 are similar to the configuration and operating mechanism of the supporting structure 110, the supporting plate 112, the fixing component 114, the circuit board 120, the assembling hole 120a, the elastic components 130, the through hole 130a, the first compressible portion 132a, the first compressible portion 132b, the second compressible portion 134 of FIG. 5 and will not be repeated here.

The difference between the embodiment of FIG. 7 and the embodiment of FIG. 5 lies in: the fixing component 214 is a tenon; the through portion 214a includes at least one elastic arm E (a plurality are illustrated); the restricting portion 214b is connected to the elastic aim E and is adapted to pass through the through hole 230a of the elastic components 230 by an elastic deformation of the elastic arm E. Under this configuration, a user only needs to place the circuit board 220 above the supporting plate 212 to align the elastic components 230 on the circuit board 220 with the fixing component 214 and apply a downward force to the circuit board 220 such that the restricting portion 214b passes through the through hole 230a and engages with the elastic component 230 to quickly assemble the circuit board onto the supporting structure 110. In this way, screwing is not needed to disassemble the circuit board 220 and the supporting structure 210, achieving an effect of quick disassembly.

In the present embodiment, an outer diameter L2 of the restricting portion 214b along the second direction D2 and the third direction D3 is greater than an outer diameter L1 of the through portion 214a along the second direction D2 and the third direction D3. In addition a hole diameter L3 of the assembling hole 220a along the second direction D2 and the third direction D3 is greater than the outer diameter L2 of the restricting portion 214b along the second direction D2 and the third direction D3, such that the restricting portion 214b is able to pass through the through hole 230a by the elastic deformation of the elastic arm E and elastic components 230, and engage with the elastic component 230. In other embodiments, the restricting portion 214b and the through portion 214a may be other suitable outer diameters and the assembling hole 220a may be other suitable hole diameters, and it should not be construed as a limitation to the invention.

FIG. 8 is a partial plan view diagram of a circuit board and an elastic component according to another embodiment of the invention. In the embodiment of FIG. 8, a configuration and operating mechanism of a circuit board 320, an assembling hole 320a, an elastic components 330, a through hole 330a are similar to the configuration and operating mechanism of the circuit board 120, the assembling hole 120a, the elastic components 130, the through hole 130a, the first compressible portion 132a, the first compressible portion 132b, the second compressible portion 134 of FIG. 4 and will not be repeated here. The difference between the embodiment of FIG. 8 and the embodiment of FIG. 4 lies in: the circuit board 320 has a slot 320b, wherein the slot 320b is connected between a side edge 320c and an assembling hole 320a of the circuit board 320. In this way, the elastic component 330 may be assembled to the assembling hole 320a from the side edge 320c of the circuit board 320 through the slot 320b, such that the assembly of the elastic component 330 is more convenient.

In summary, in an electronic assembly of the invention, an elastic component is disposed at an assembling hole of a circuit board. The elastic component has a first compressible portion located outside the assembling hole and a second compressible portion located inside the assembling hole. When a first electrical connector on the circuit board is inserted to a corresponding second electrical connector, the elastic component may absorb an error margin in the manufacturing and assembly of the electronic assembly in a first direction by an elastic compression of the first compressible portion along the first direction, and absorb the error margin in the manufacturing and assembly of the electronic assembly in a second direction and a third direction by the elastic compression of the second compressible portion along the second direction and the third direction D3, such that the first electrical connector may be inserted to the corresponding second electrical connector smoothly. The first direction, the second direction and the third direction are three axis directions mutually perpendicular to each other in space, namely, the elastic component may absorb the error margins in the manufacturing and assembly of the electronic assembly in all directions by the elastic compression of the first compressible portion and the second compressible portion. In addition during the process of inserting the first electrical connector to the corresponding second electrical connector, the elastic components may cushion the impact generated by the insertion, such that the electronic assembly may have a good vibration damping effect to prevent the circuit board and the components thereon from being damaged during the insertion process due to excessive vibration.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electronic assembly, comprising:
a supporting structure;
a circuit board, having at least one assembling hole and a first electrical connector, wherein the circuit board is assembled to the supporting structure through the assembling hole, and the first electrical connector is adapted to connect to a second electrical connector; and
at least one elastic component, disposed at the assembling hole, wherein the elastic component comprises at least one first compressible portion and a second compressible portion connected to each other, the first compressible portion is located outside the assembling hole and adapted to be compressed between the supporting structure and the circuit board along a first direction, the second compressible portion is located inside the assembling hole and adapted to be compressed between the supporting structure and the circuit board along a second direction and a third direction, the first direction, the second direction and the third direction are mutually perpendicular.

2. The electronic assembly as claimed in claim 1, wherein the supporting structure comprises a supporting plate and at least one fixing component, the supporting plate supports the circuit board, the fixing component comprises a through portion and a restricting portion connected to each other, the elastic component has a through hole, the through portion penetrates the through hole and connects to the supporting plate, the restricting portion restricts the elastic component and the circuit board on the supporting plate.

3. The electronic assembly as claimed in claim 2, wherein the first compressible portion is located between the restricting portion and the circuit board or located between the supporting plate and the circuit board, and is adapted to be compressed by the restricting portion and the circuit board along the first direction or to be compressed by the supporting plate and the circuit board along the first direction.

4. The electronic assembly as claimed in claim 2, wherein the second compressible portion is located between the through portion and an inner wall of the assembling hole, and is adapted to be compressed by the through portion and the circuit board along the second direction and the third direction.

5. The electronic assembly as claimed in claim 2, wherein an outer diameter of the restricting portion along the second direction and the third direction is greater than an outer diameter of the through portion along the second direction and the third direction.

6. The electronic assembly as claimed in claim 2, wherein a hole diameter of the assembling hole along the second direction and the third direction is greater than an outer diameter of the restricting portion along the second direction and the third direction.

7. The electronic assembly as claimed in claim 2, wherein a thickness of the elastic component along the first direction is greater than or equal to a thickness of the through portion along the first direction.

8. The electronic assembly as claimed in claim 2, wherein the fixing component comprises a threaded portion, the threaded portion is connected to the restricting portion and screwed to the through portion.

9. The electronic assembly as claimed in claim 2, wherein the through portion comprises at least one elastic arm, the restricting portion is connected to the elastic arm and is adapted to pass through the through hole by an elastic deformation of the elastic arm.

10. The electronic assembly as claimed in claim 2, wherein the second compressible portion contacts an inner wall of the assembling hole and the through portion simultaneously.

11. The electronic assembly as claimed in claim 1, wherein the at least one first compressible portion comprises two first compressible portions, the second compressible portion is connected between the two first compressible portions, the two first compressible portions are located at two opposite sides of the circuit board respectively.

12. The electronic assembly as claimed in claim 1, wherein a material of the elastic component is an insulation material.

13. The electronic assembly as claimed in claim 1, wherein the circuit board has a slot, the slot is connected between a side edge of the circuit board and the assembling hole.

14. The electronic assembly as claimed in claim 1, wherein the second electrical connector is disposed on a frame, the first electrical connector is adapted to connect to the second electrical connector by moving the supporting structure along the frame.

15. The electronic assembly as claimed in claim 1, wherein the first electrical connector is a tell final assembly independently disposed on the circuit board or a card edge connector of the circuit board.
